(19) United States
(12) Patent Application Publication
(10) Pub. No.: US 2018/0108519 A1
(43) Pub. Date: Apr. 19, 2018

(54) POWER DELIVERY FOR HIGH POWER IMPULSE MAGNETRON SPUTTERING (HiPIMS)

(71) Applicant: APPLIED MATERIALS, INC., Santa Clara, CA (US)

(72) Inventors: VIACHSLAV BABAYAN, Sunnyvale, CA (US); ADOLPH MILLER ALLEN, Oakland, CA (US); MICHAEL STOWELL, Loveland, CO (US); ZHONG QIANG HUA, Saratoga, CA (US); CARL R. JOHNSON, Tracy, CA (US); VANESSA FAUNE, San Jose, CA (US); JINGJING LIU, Milpitas, CA (US)

(21) Appl. No.: 15/691,157

(22) Filed: Aug. 30, 2017

Related U.S. Application Data
(60) Provisional application No. 62/409,052, filed on Oct. 17, 2016.

(51) Int. Cl. H01J 37/34; C23C 14/34; C23C 14/35; H01B 9/02

(52) U.S. Cl. CPC H01J 37/3467; H01J 37/3405; H01B 9/02; C23C 14/3485; C23C 14/35; H01J 37/3488

(57) ABSTRACT

A system for the generation and delivery of a pulsed, high voltage signal for a process chamber includes a remotely disposed high voltage supply to generate a high voltage signal, a pulser disposed relatively closer to the process chamber than the high voltage supply, a first shielded cable to deliver the high voltage signal from the remotely disposed high voltage supply to the pulser to be pulsed, and a second shielded cable to deliver a pulsed, high voltage signal from the pulser to the process chamber. A method for generating and delivering a pulsed, high voltage signal to a process chamber includes generating a high voltage signal at a location remote from the process chamber, delivering the high voltage signal to a location relatively closer to the process chamber be pulsed, pulsing the delivered, high voltage signal, and delivering the pulsed, high voltage signal to the process chamber.

### CROSS-REFERENCE TO RELATED APPLICATIONS

This application claims benefit of U.S. provisional patent application Ser. No. 62/409,052, filed Oct. 17, 2016, which is herein incorporated by reference in its entirety.

### FIELD

Embodiments of the present disclosure relate to power delivery for plasma processing in semiconductor process chambers.

### BACKGROUND

Sputtering, also known as physical vapor deposition (PVD), is a method of forming features in integrated circuits. Sputtering deposits a material layer on a substrate. A source material, such as a target, is bombarded by ions strongly accelerated by an electric field. The bombardment ejects material from the target, and the material then deposits on the substrate.

For applications requiring deposition of dielectric materials in PVD chambers, a higher voltage pulsed DC generator is required in comparison to metal deposition applications. To maximize power delivery to a target, a voltage of the DC pulses can be increased, however there is a limit to how high voltage can be increased until a target starts arcing and generating particles. Alternatively, a pulsing frequency can be increased while maintaining the same pulse ON time, however there is a limit to how fast high voltage (HV) power supplies can switch.

### SUMMARY

A method and system for generating and delivering a pulsed, high voltage signal to a process chamber are described herein. In some embodiments, a method for delivering a pulsed, high voltage signal to a process chamber includes generating a high voltage signal at a location remote from the process chamber, delivering the high voltage signal to a location relatively closer to the process chamber be pulsed, pulsing the delivered, high voltage signal and delivering the pulsed, high voltage signal to the process chamber.

In some embodiments, to improve power delivery, the pulsed, high voltage signal may be delivered to the process chamber using a low inductance shielded cable.

In some embodiments, a system for the generation and delivery of a pulsed, high voltage signal for a process chamber includes a remotely disposed high voltage supply generating a high voltage DC signal, a pulser disposed relatively closer to the process chamber than the high voltage DC supply, a first shielded cable for delivering the high voltage DC signal from the remotely disposed high voltage supply to the pulser to be pulsed and a second shielded cable for delivering the pulsed, high voltage signal from the pulser to the process chamber.

In some embodiments, the pulser is located on a top surface of the process chamber. In addition, in some embodiments, the second shielded cable is a low inductance shielded cable to increase power delivery efficiency.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic cross-sectional view of a physical vapor deposition (PVD) chamber in accordance with some embodiments of the present disclosure.

FIG. 2 depicts a high level block diagram of a system for power delivery for HiPIMS applications in accordance with an embodiment of the present principles.

FIG. 3 depicts a high level block diagram of a system for power delivery for HiPIMS applications in accordance with an alternate embodiment of the present principles.

FIG. 4A depicts a screen shot of an oscilloscope measurement of a high voltage signal being delivered by a high inductance shielded cable having an inductance rating greater than 150 nH/ft.

FIG. 4B depicts a screen shot of an oscilloscope measurement of a high voltage signal being delivered by a low inductance shielded cable having an inductance rating less than 50 nH/ft.

FIG. 5 depicts a flow diagram of a method for generating and delivering a pulsed, high voltage signal to a process chamber in accordance with an embodiment of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure relate to a high resolution process system that provides a high power impulse magnetron sputtering (HiPIMS) generator and means thereof. For example, a high voltage DC pulse may be provided to a target of a process chamber in two phases. In a first phase a high voltage DC signal is provided. In a second phase, the voltage is pulsed at a location near the target and the process chamber to reduce an impedance associated with a delivery of the pulsed, high voltage DC signal by, for example a long delivery cable. Embodiments of the present disclosure may advantageously reduce, control, or eliminate a loss of power associated with the delivery of a pulsed, high power DC signal to a process chamber.

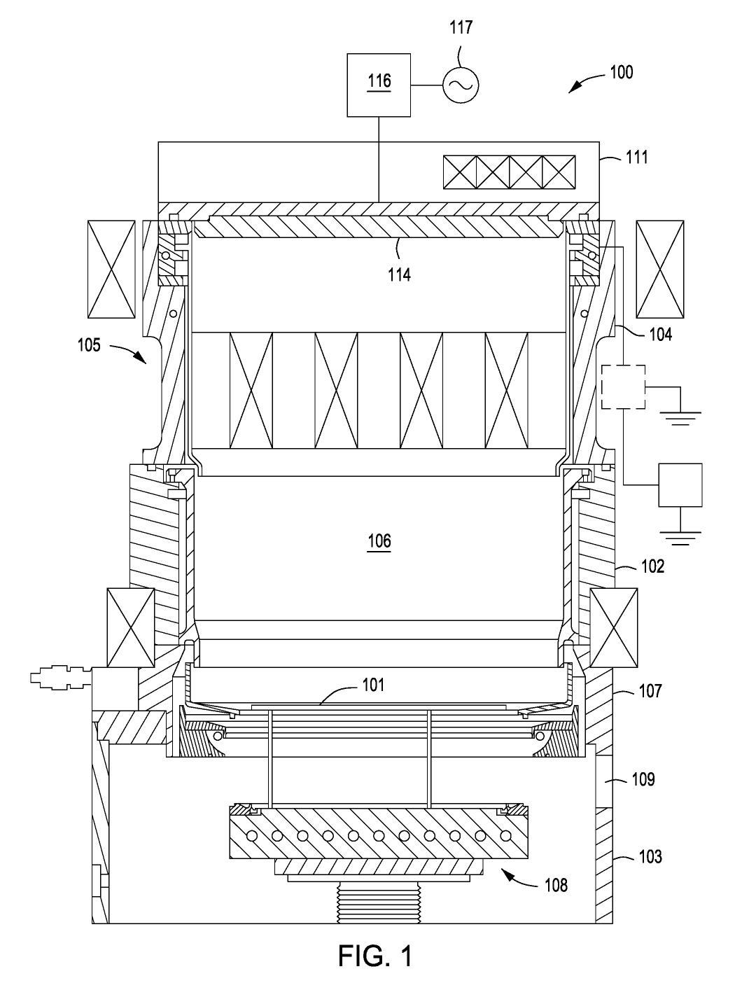

FIG. 1 depicts an illustrative PVD chamber (chamber 100), e.g., a sputter process chamber, suitable for sputter depositing materials on a substrate in accordance with embodiments of the present disclosure. Illustrative examples of suitable PVD chambers that may be adapted to benefit from the disclosure include the ALPS® Plus and SIP ENCORE® PVD processing chambers, both commercially available from Applied Materials, Inc., Santa Clara, of California. Other processing chambers available from Applied Materials, Inc. as well as other manufacturers may also be adapted in accordance with the embodiments described herein.

All of the components of a processing chamber will not be described or illustrated herein. Only the components necessary for understanding the embodiments in accordance with the present principles will be described herein. The process chamber 100 of FIG. 1 illustratively comprises an upper sidewall 102, a lower sidewall 103, a ground adapter 104, and a lid assembly 111 defining a body 105 that encloses an interior volume 106 thereof. An adapter plate 107 may be disposed between the upper sidewall 102 and the lower sidewall 103. A substrate support, such as a pedestal 108, is disposed in the interior volume 106 of the process chamber 100. A substrate transfer port 109 is formed in the lower sidewall 103 for transferring substrates into and out of the interior volume 106.

In some embodiments, the process chamber 100 is configured to deposit, for example, titanium, aluminum oxide, aluminum, aluminum oxynitride, copper, tantalum, tantalum nitride, tantalum oxynitride, titanium oxynitride, tungsten, tungsten nitride, or other dielectric materials, on a substrate, such as the substrate 101.

The ground adapter 104 may support a sputtering source 114, such as a target fabricated from a material to be sputter deposited on a substrate. In some embodiments, the sputtering source 114 may be fabricated from dielectric materials, titanium (Ti) metal, tantalum metal (Ta), tungsten (W) metal, cobalt (Co), nickel (Ni), copper (Cu), aluminum (Al), alloys thereof, combinations thereof, or the like.

The sputtering source 114 (target) may be coupled to a source assembly 116 comprising a power supply 117 for the sputtering source 114. In some embodiments, the power supply 117 may be a high voltage DC power supply or a pulsed, high voltage DC power supply.

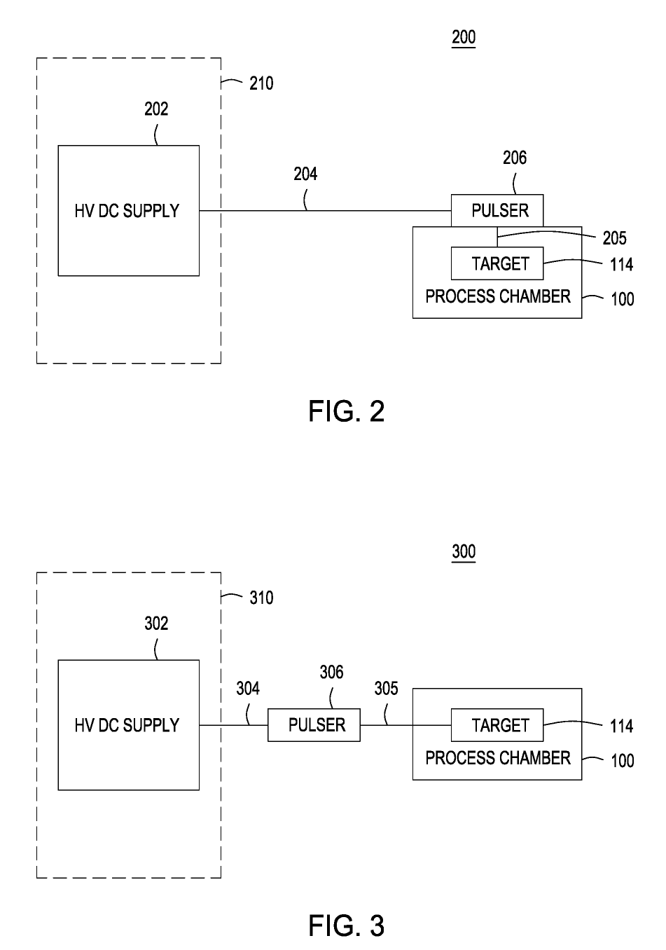

FIG. 2 depicts a high level block diagram of a system 200 for the generation and delivery of a pulsed, high voltage DC signal for, for example, a target of a process chamber, such as the target 114 of the process chamber 100 of FIG. 1, in accordance with an embodiment of the present principles. The system 200 of FIG. 2 illustratively comprises a high voltage DC power supply 202, a high voltage, shielded cable 204, a pulser 206 and a process chamber 100. In accordance with the present principles the high voltage DC power supply 202 and the pulser 206 comprise separate components. In some embodiments in accordance with the present principles, the high voltage DC power supply 202 is located remotely from the pulser 206 and the process chamber 100. That is, typically process chambers are located in clean rooms. Because clean room environments are expensive to maintain, clean room space is limited. In the embodiment of FIG. 2, the high voltage DC power supply 202 is illustratively located in a subfab 210, a room below the clean room in which large pumps, compressors and power sources that don't have to be in the clean room environment are located.

As such, in the embodiment of FIG. 2, the high voltage, shielded cable 204 has to be long enough to deliver the high voltage DC signal from the high voltage DC power supply 202 in the subfab 210 to the pulser 206. In some embodiments in accordance with the present principles, the high voltage shielded cable 204 is approximately seventy-five (75) feet long.

In some embodiments the high voltage DC power supply 202 can comprise a step up transformer, a rectifier diode assembly to convert AC voltage to DC and an array of capacitors used to store charge, along with control circuitry and high power transistors used to switch voltage levels. In some embodiments, the pulser 206 can comprise an array of capacitors at the input and high voltage power transistors used to generate pulsed DC signal along with control electronics.

In accordance with the present principles, the pulser 206 is located relatively closer to the process chamber 100 than the high voltage DC power supply 202. As such, a loss associated with the delivery of a pulsed, high voltage signal to the target 114 of the process chamber due to impedance of a delivery cable (e.g., the high voltage, shielded cable 204 of FIG. 2) is reduced because, in accordance with the present principles, the pulsing is performed relatively closer to the process chamber 100 than a location of the high voltage DC power supply 202.

In the system 200 of FIG. 2, the pulser 206 is illustratively located directly on the lid assembly 111 of the process chamber 100. The pulser receives a high voltage DC signal from the high voltage DC power supply 202 over the shielded cable 204. The pulser 206 pulses the received high voltage DC signal and delivers a pulsed, high voltage DC signal to the target 114 of the process chamber 100 via a cable 205 internal to the process chamber 100.

In the embodiment of the system 200 FIG. 2, because the location of the pulser 206 is closer to the plasma chamber 100 than the high voltage DC power supply 202, and in the embodiment of FIG. 2 specifically on the plasma chamber 100, and the due to the fact that the high voltage DC power supply 202 and the pulser 206 comprise separate components, the high voltage shielded cable 204 may comprise a standard DC cable to deliver the high voltage DC signal from the DC power supply 202 to the pulser 206.

Although in the embodiment of the present principles illustrated in FIG. 2, the pulser 206 is illustratively depicted as being mounted directly on the process chamber 100, in alternate embodiments in accordance with the present principles, a pulser is located relatively closer to the process chamber than the high voltage power supply however is not located directly on the process chamber. For example, FIG. 3 depicts a high level block diagram of a system 300 for the generation and delivery of a pulsed, high voltage signal in accordance with an alternate embodiment of the present principles. The system 300 of FIG. 3 illustratively comprises a high voltage DC power supply 302, a first high voltage, shielded cable 304, a second high voltage, shielded cable 305, a pulser 306 and a process chamber, such as the process chamber 100 of FIG. 1. In the embodiment of FIG. 3, the high voltage DC power supply 302 of FIG. 3 is located remotely from the pulser 206 and the process chamber 100. In the embodiment of FIG. 3, the high voltage DC power supply 302 is illustratively located in a subfab 310. As such, the first high voltage, shielded cable 304 has to be long enough to deliver the high voltage DC signal from the high voltage DC power supply 302 in the subfab 310 to the pulser 306.

In the power delivery system 300 of FIG. 3, the pulser 306 receives a high voltage DC signal from the high voltage DC power supply 302 over the first high voltage, shielded cable 304. The pulser 306 pulses the received high voltage DC signal and transmits a pulsed, high voltage DC signal to the process chamber 100 over the second high voltage, shielded cable 305. In the embodiment of FIG. 3, the pulser 306 delivers the pulsed, high voltage DC signal to the target 114 in the process chamber 100. In the embodiment of FIG. 3, because the location of the pulser 306 is closer to the plasma chamber 100 than the high voltage DC power supply 202 and due to the fact that the high voltage DC power supply 302 and the pulser 306 comprise separate components, the first and second high voltage, shielded cables 304, 305 may comprise standard DC cables to communicate high voltage DC signal from the DC power supply 302 in the subfab 310 to the pulser 306 and to transmit the pulsed, high voltage signal to the target 114 in the process chamber 100.

In some embodiments in accordance with the present principles, the second high voltage, shielded cable 305 of FIG. 3 may comprise a low inductance shielded cable. The inventors determined that by minimizing the impedance of a power delivery cable, a maximum power delivered by the cable may be optimized. That is, a simplified model of the impedance of a cable can be characterized as Z=R+2*pi*F*L. In terms of a DC signal, impedance is mainly resistive because F=0 and inductance has little effect. As such, as frequency increases, impedance increases and inductance of the cable has a bigger effect. For a given pulse voltage, a lower inductance cable will result in a higher rate of rise of the current during each pulse, which results in higher power delivery of the pulsed, HV DC signal communicated by the pulser 306 to the target 114 of the process chamber 100.

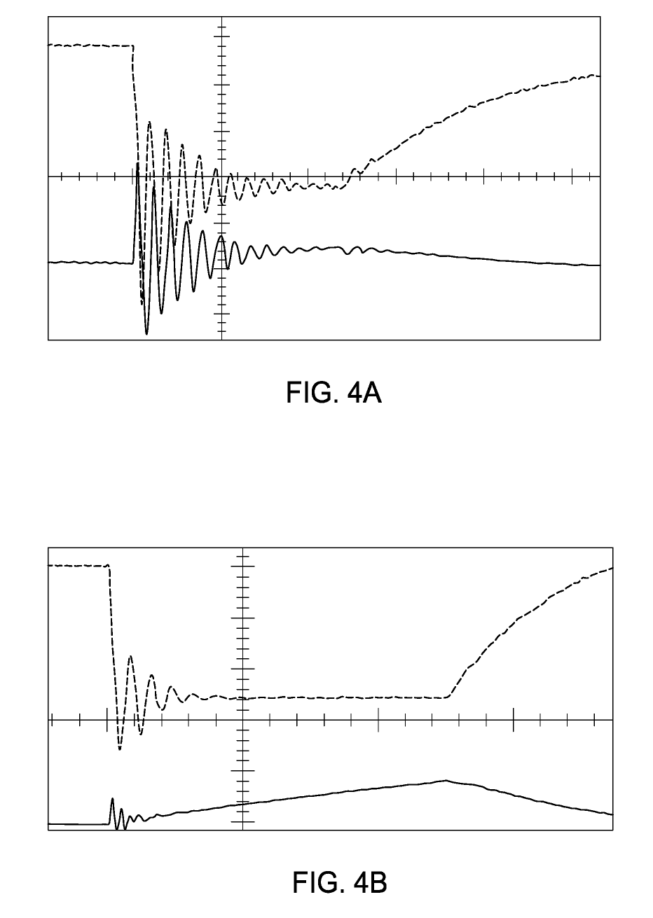

For example, FIG. 4A depicts a screen shot of an oscilloscope measurement of a high voltage signal being delivered by a high inductance shielded cable having an inductance rating greater than 150 nH/ft. As depicted in FIG. 4A, oscillations produced by the delivery of the high voltage signal through the high inductance shielded cable causes an unstable delivery of power. As depicted in FIG. 4A, the low instantaneous rate of current change (di/dt) in the power delivery system results in limited power delivery.

FIG. 4B depicts a screen shot of an oscilloscope measurement of a high voltage signal being delivered by a low inductance shielded cable having an inductance rating less than 50 nH/ft. As depicted in FIG. 4B, there are substantially fewer oscillations produced by the delivery of the high voltage signal through the low inductance shielded cable. As depicted in FIG. 4B, the low inductance shielded cable provides 25 to 30% higher current for similar voltage level and pulse duration then in the high inductance shielded cable of FIG. 4A.

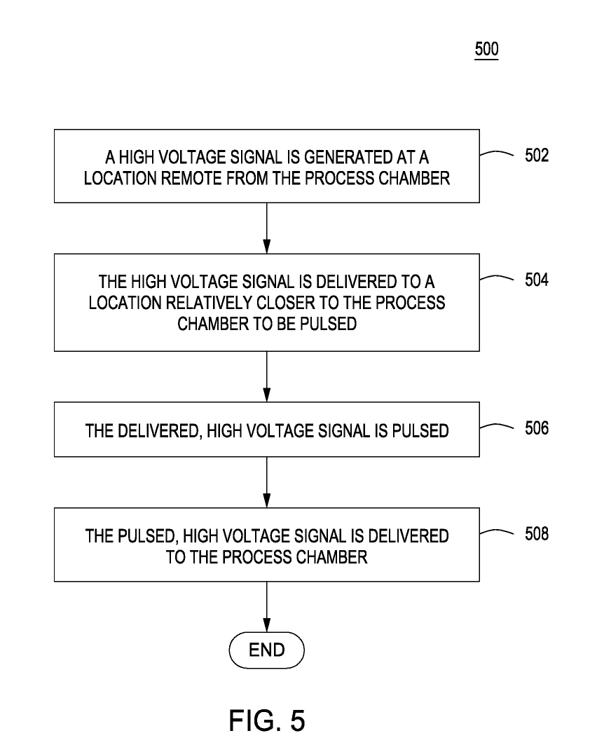

FIG. 5 depicts a flow diagram of a method 500 for generating and delivering a pulsed, high voltage signal to a process chamber in accordance with an embodiment of the present principles. The method 500 may begin at 502 during which a high voltage signal is generated at a location remote from the process chamber. The method may then proceed to 504.

At 504, the high voltage signal is delivered to a location relatively closer to the process chamber to be pulsed. The method 500 may then proceed to 506.

At 506, the delivered, high voltage signal is pulsed. The method 500 may then proceed to 508.

At 508, the pulsed, high voltage signal is delivered to the process chamber. The method 500 may then be exited.

While the foregoing is directed to embodiments of the present disclosure, other and further embodiments of the disclosure may be devised without departing from the basic scope thereof.

1. A system for generation and delivery of a pulsed, high voltage signal for a process chamber, comprising:
a remotely disposed high voltage supply to generate a high voltage signal;
a pulser disposed relatively closer to the process chamber than the high voltage supply;
a first shielded cable to deliver the high voltage signal from the remotely disposed high voltage supply to the pulser to be pulsed; and
a second shielded cable to deliver a pulsed, high voltage signal from the pulser to the process chamber.

2. The system of claim 1, wherein the process chamber is located in a clean room and the high voltage supply is located in a subfab facility.

3. The system of claim 2, wherein the subfab facility comprises a room below the clean room.

4. The system of claim 1, wherein the pulser is located on a top surface of the process chamber.

5. The system of claim 4, wherein the pulsed, high voltage signal from the pulser is delivered to the process chamber via a cable internal to the process chamber.

6. The system of claim 1, wherein the second shielded cable comprises a low inductance shielded cable.

7. The system of claim 1, wherein the pulsed, high voltage signal is delivered to a target of the process chamber.

8. The system of claim 1, wherein at least one of the first shielded cable or the second shielded cable comprise a standard DC cable.

9. A method for generating and delivering a pulsed, high voltage signal to a process chamber, comprising:
generating a high voltage signal at a location remote from the process chamber;
delivering the high voltage signal to a location relatively closer to the process chamber to be pulsed;
pulsing the delivered, high voltage signal; and
delivering the pulsed, high voltage signal to the process chamber.

10. The method of claim 9, wherein the high voltage signal is generated by a high voltage supply located in a subfab facility.

11. The method of claim 10, wherein the subfab facility comprises a separate room from a clean room in which the process chamber is located.

12. The method of claim 9, wherein the high voltage signal is pulsed by a pulser located between a location of the high voltage supply and a location of the process chamber.

13. The method of claim 9, wherein the high voltage signal is delivered for pulsing using a shielded cable.

14. The method of claim 9, wherein the pulsed, high voltage signal is delivered to the process chamber using a shielded cable.

15. The method of claim 14, wherein the shielded cable comprises a low inductance, shielded cable.
